(19) United States
(12) Patent Application Publication
(10) Pub. No.: US 2012/0264268 A1
(43) Pub. Date: Oct. 18, 2012

(54) METHODS OF FORMING ELECTRICAL ISOLATION REGIONS BETWEEN GATE ELECTRODES

(75) Inventor: Ji-Hwon Lee, Sunon-si (KR)

(73) Assignee: Samsung Electronics Co., Ltd.

(21) Appl. No.: 13/441,124

(22) Filed: Apr. 6, 2012

(30) Foreign Application Priority Data
Apr. 14, 2011 (KR) 10-2011-0034689

(51) Int. Cl. H01L 21/336; H01L 21/76; H01L 21/02

(52) U.S. Cl. 438/289; 438/669; 438/424; 257/E21.02; 257/E21.54; 257/E21.409; 438/296

(57) ABSTRACT

Methods of forming nonvolatile memory devices include forming first and second floating gate electrodes of first and second nonvolatile memory cells, respectively, at side-by-side locations on a substrate. The substrate is selectively etched to define a trench therein extending between the first and second floating gate electrodes. The trench is at least partially filled with a first electrical insulation pattern. An inorganic polysilazane-type spin-on-glass (SOG) layer is conformally deposited on the first and second floating gate electrodes and on the first electrical insulation pattern and then partially removed.

### REFERENCE TO PRIORITY APPLICATION

This application claims priority under 35 USC §119 to Korean Patent Application No. 10-2011-034689, filed Apr. 14, 2011 in the Korean Intellectual Property Office (KIPO), the disclosure of which is hereby incorporated herein by reference in their entirety.

### FIELD OF THE INVENTION

The present invention relates to isolation layer structures and methods of forming the same and, more particularly, to isolation layer structures that are formed in both cell and peripheral regions of semiconductor devices and methods of forming the same.

### BACKGROUND

In manufacturing semiconductor devices, shallow trench isolation processes are performed for defining active regions where devices are formed and also define isolation regions that isolate the active regions from each other. Inner widths and depths of the isolation regions can be different from each other according to each region of the substrate. Thus, the sizes of the trenches for the device isolation regions can be different from each other. Filling the different-sized trenches with an insulation material that is free of voids can be challenging. Moreover, multiple photolithography, deposition and polishing processes may be required to define and fill different-sized trenches, which means the formation of void-free isolation regions can require complex and expensive processing.

### SUMMARY

Methods of forming integrated circuit devices according to embodiments of the invention include forming an electrically conductive layer on a substrate and patterning the electrically conductive layer into first and second electrically conductive patterns by selectively etching the electrically conductive layer to define an opening therein that exposes the substrate. The opening is filled with an inorganic polysilazane-type spin-on-glass (SOG) material to define a first electrically insulating region extending between the first and second electrically conductive patterns. The electrically insulating region is removed from within the opening to expose sidewalls of the first and second electrically conductive patterns. The patterning step may be followed by selectively etching the substrate exposed by the opening to define a trench within the substrate. The filling step, which may be preceded by forming a silicon oxide insulation pattern within the trench, may include depositing an inorganic polysilazane-type spin-on-glass (SOG) layer on the silicon oxide insulation pattern. This polysilazane-type spin-on-glass (SOG) layer may be a tonen silazene (TOSZ) material. This TOSZ material may be prebaked at a temperature in a range from 150° C. to 250° C. and then baked at a temperature in a range from 700° C. to 850° C.

Additional embodiments of the invention include methods of forming a nonvolatile memory device by forming first and second floating gate electrodes of first and second nonvolatile memory cells, respectively, at side-by-side locations on a substrate. The substrate is selectively etched to define a trench therein extending between the first and second floating gate electrodes. The trench is at least partially filled with a first electrical insulation pattern. An inorganic polysilazane-type spin-on-glass (SOG) layer is conformally deposited on the first and second floating gate electrodes and on the first electrical insulation pattern. The inorganic polysilazane-type spin-on-glass (SOG) layer is partially removed from between the first and second floating gate electrodes. A control gate electrode is formed on upper sidewalls of the first and second floating gate electrodes and on a remaining portion of the inorganic polysilazane-type spin-on-glass (SOG) layer extending between the first and second floating gate electrodes. The inorganic polysilazane-type spin-on-glass (SOG) layer may be a tonen silazene (TOSZ) layer, which is conformally deposited on the first and second floating gate electrodes and on the first electrical insulation pattern. This polysilazane-type spin-on-glass (SOG) layer may be a tonen silazene (TOSZ) material. This TOSZ material may be prebaked at a temperature in a range from 150° C. to 250° C. and then baked at a temperature in a range from 700° C. to 850° C.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a cross-sectional view illustrating an isolation layer structure in accordance with example embodiments of the invention;

FIGS. 2 through 10 are cross-sectional views illustrating a method of forming an isolation layer structure as shown in FIG. 1;

FIG. 11 is a cross-sectional view illustrating a nonvolatile memory device in accordance with example embodiments; and

FIG. 12 is a cross-sectional view illustrating a method of manufacturing a nonvolatile memory device as shown in FIG. 11.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, example embodiments will be explained in detail with reference to the accompanying drawings.

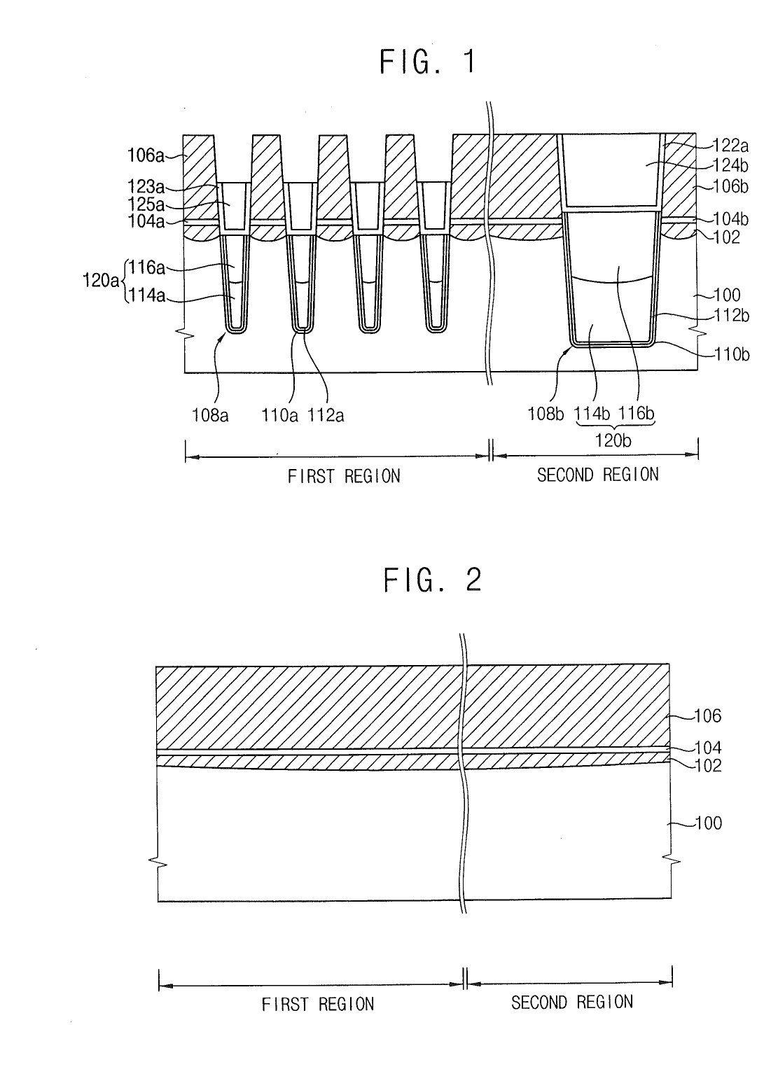

FIG. 1 is a cross-sectional view illustrating an isolation layer structure in accordance with example embodiments. The isolation layer structure in accordance with the present example embodiments may be applied to a field region of a nonvolatile memory device. Referring to FIG. 1, a substrate 100 wherein first and second regions are defined is provided. The first region may be referred to as a cell region where memory cells are to be formed. The second region may be referred to as a peripheral region where peripheral circuits are to be formed. First preliminary trenches having a first width and a first depth may be formed in the cell region of the substrate 100. Further, second preliminary trenches having a second width and a second depth are formed in the peripheral region of the substrate 100. The second width is wider than the first width and the second depth is deeper than the first depth. For example, the first width is no more than 30 nm.

The portions where the first and second preliminary trenches are formed are provided as field regions and the planar portions where the first and second preliminary trenches are formed are not formed are provided as active regions. The first and second preliminary trenches have a line shape that is extended in a first direction. Impurities 102 are doped into regions under the planar surface in the active regions of the substrate 100 so as to control a threshold voltage of a transistor. Example of the impurities 102 may include boron.

In the first region, tunnel oxide layer patterns 104a and floating gate electrodes 106a are provided on the surface portions in the active regions of the substrate 100. The tunnel oxide layer patterns 104a and the floating gate electrodes 106a have a line shape that is extended in the first direction. The tunnel oxide layer patterns 104a and the floating gate electrodes 106a that are formed in the first region are provided as parts of cell transistors of a nonvolatile memory device. In the second region, oxide layer patterns 104b and gate patterns 106b are provided on the surface portion in the active region of the substrate 100. The oxide layer patterns 104b and the gate patterns 106b have a line shape that is extended in the first direction. The oxide layer patterns 104b and the gate patterns 106b that are formed in the second region are provided as parts of transistors that constitute a peripheral circuit. The gate patterns 106b have a line width that is wider than that of the floating gate electrodes 106a.

The floating gate electrodes 106a and the gate patterns 106b may comprise a same material, and may comprise, for example, polysilicon. As an example embodiment, the floating gate electrodes 106a and the gate patterns 106b may have composite layers that are formed by stacking polysilicon carbide (SiC) patterns and polysilicon patterns. According to another example embodiment, the floating gate electrodes 106a and the gate patterns 106b may comprise polysilicon patterns.

A first gap between the floating gate electrodes 106a formed in the first region is communicated with the first preliminary trench. A second gap between the gate patterns 106b formed in the second region is communicated with the second preliminary trench. The first gap and the first preliminary trench form a first trench 108a. Also, the second gap and the second preliminary trench form a second trench 108b.

First, an isolation layer pattern in the first trench 108a will be explained. A first sidewall oxide layer pattern 110a is provided along a profile of sidewalls and a bottom surface of the first trench 108a. Also, a first liner layer pattern 112a is formed on the first sidewall oxide layer pattern 110a along a profile of sidewalls and a bottom surface of the first trench 108a. As a material that may be used for the first liner layer pattern 112a, silicon oxide may be mentioned. Example of the silicon oxide may include middle temperature oxide. The first liner layer pattern 112a is provided for suppressing the impurities 102 doped in the channel region of the substrate 100 from being diffused into the first trench 108a. When the first liner layer pattern 112a comprises silicon nitride, electrons may be trapped inside the first liner layer pattern 112a, which damages the reliability of the nonvolatile memory device. Therefore, forming the first liner layer pattern 112a by using silicon nitride is not preferable.

A first insulation layer pattern 120a is provided on the first liner layer pattern 112a so as to partially fill up the lower portion of the first trench 108a. The first insulation layer pattern 120a is provided for reducing an aspect ratio of the first trench 108a. The first insulation layer pattern 120a may be formed by using a material that hardly causes a dislocation in the first trench during the deposition process for the first insulation layer 120a. Further, the first insulation layer pattern 120 may be formed by using a material that suppresses the diffusion of the doped impurities to control the threshold voltage of the substrate.

When the upper surface of the first insulation layer pattern 120a is higher than a bottom surface of a floating gate electrode, there is a high probability that defects due to a void may be generated. Thus, the upper surface of the first insulation layer pattern 120a is preferably lower than the bottom surface of the floating gate electrode. Materials that may be used for the first insulation layer pattern 120a may include undoped silicate glass (USG). As another example embodiment, materials that may be used for the first insulation layer pattern 120a, may include high density plasma oxide (HDP oxide), middle temperature oxide, hot temperature oxide, ozone-TEOS, etc.

When the lower portions of the first and second trenches 108a and 108b are filled up with polysilazane-type SOG, the substrate defects due to a dislocation may be incurred at the lower corners of the first and second trenches 108a and 108b. Particularly, when the polysilazane-type SOG is used for the second trench 108b that has a relatively wide width, substrate defects due to a dislocation may occur at the lower corner of the second trench 108b. In the isolation layer structure in accordance with the present example embodiment, the material for filling up the lower portion of the second trench 108b is the same as the material for the first insulation layer pattern 120a. Therefore, the above polysilazane-type SOG is not preferable for the first insulation layer pattern 120a that may fill up the lower portions of the plurality of the first trenches 108a.

A third liner layer pattern 123a is provided on a portion of an inner sidewall of the first trench 108a and on a surface of the first insulation layer pattern 120a. The third liner layer pattern 123a may comprise silicon oxide. The third liner layer pattern 123a may comprise the same material as the first liner layer pattern 112a. A third insulation layer pattern 125a is provided on the third liner layer pattern 123a so as to partially fill up the inside of the first trench 108a. The upper sidewall portions of the floating gate electrodes 106a that are located both side of the third insulation layer pattern 125a are exposed. Further, the bottom surface of the third insulation layer patter 125a is lower than the bottom surface of the floating gate electrode 106a.

A material that may fill up the first trench 108a having a narrow width of no more than 30 nm without incurring any void in the first trench 108a may be used for the third insulation layer pattern 125a. Particularly, examples of a material that may be used for the third insulation layer pattern 125a may include an inorganic polysilazane-type SOG material. Examples of the inorganic polysilazane-type SOG material may include Tonen Silazene (TOSZ).

Materials such as undoped silicate glass (USG), high density plasma oxide (HDP oxide), middle temperature oxide, hot temperature oxide, ozone-TEOS, etc. may generate a void when these materials fills up the first trench having a narrow width no more than 30 nm, which is unsuitable.

As explained above, the first insulation layer pattern 120a is provided to fill up the lower space of the first trench 108a, which is lower than the bottom surface of the floating gate electrode 106a so that the dislocation defects is suppressed and the diffusion of the impurities is reduced. Therefore, erroneous operation of the device due to the dislocation or diffusion of the impurities is suppressed and the reliability of the device is improved.

Further, the third insulation layer pattern 125a is provided to fill up the upper space of the first trench 108a, which is higher than the bottom surface of the floating gate electrode 106a so that no void may be formed. Therefore, a defect such as excessive recession of the field region due to the void formed at a gap between the floating gate electrodes 106a may be reduced.

A second sidewall oxide layer pattern 110b is provided along a profile of sidewalls and a bottom surface of the second trench 108b. Also, a second liner layer pattern 112b is formed on the second sidewall oxide layer pattern 110b along a profile of sidewalls and a bottom surface of the second trench 108b. As a material that may be used for the second liner layer pattern 112b may be the same as for the first liner layer pattern 112a. A second insulation layer pattern 120b is provided on the second liner layer pattern 112b so as to partially fill up the lower portion of the second trench 108b. The upper surface of the second insulation layer pattern 120b is higher than the upper surface of the first insulation layer pattern 120a. Further, the upper surface of the second insulation layer pattern 120b may be higher than the upper surface of the tunnel oxide layer pattern 104a.

The material that may be used for the second insulation layer pattern 120b is the same as the material for the first insulation layer pattern 120a. Materials that may be used for the second insulation layer pattern 120b may include undoped silicate glass (USG). As another example embodiment, materials that may be used for the second insulation layer pattern 120b may include high density plasma oxide (HDP oxide), middle temperature oxide, hot temperature oxide, ozone-TEOS, etc. These can be used alone or in a combination thereof. As explained above, the second insulation layer pattern 120b may be formed with a material that hardly generates a dislocation defect. Therefore, a crack due to the dislocation is hardly incurred at the corners of the second trench 108b. Further, the second insulation layer pattern 120b may be formed with a material that may suppress the diffusion of the impurities for controlling the threshold voltage of the semiconductor device. Also, the substrate portion of the sidewalls of the second trench 108b faces the second insulation layer pattern 120b. Thus, the diffusion of the impurities for controlling the threshold voltage of the semiconductor device into the second trench 108b may be effectively suppressed and the erroneous operation of the transistor due to the lower dopant concentration due to the diffusion of the impurities may be reduced.

A second liner layer pattern 122a is provided on a portion of an inner sidewall of the second trench 108b and on a surface of the second insulation layer pattern 120b. A fourth insulation layer pattern 124b is provided on the second liner layer pattern 122a so as to completely fill up the inside of the second trench 108b. The fourth insulation layer pattern 124b may comprise a material that may be used for the third insulation layer pattern 125a. Particularly, examples of the material that may be used for the fourth insulation layer pattern 124b may include TOSZ (Tonen silazene) that is an inorganic polysilazane-type SOG. As mentioned above, since the fourth insulation layer pattern 124b may be formed with a material that may hardly incur any void, the defect due to the void may be reduced.

FIGS. 2 through 10 are cross-sectional views illustrating a method of forming an isolation layer structure as shown in FIG. 1. Referring to FIG. 2, impurities 102 for controlling a threshold voltage are doped into upper portion of the substrate 100 that is defined into first and second regions. Particularly, impurities 102 are doped into a portion where cell transistors and peripheral transistors are to be formed so as to control the threshold voltages of the cell transistors and peripheral transistors. Examples of the impurities for controlling a threshold voltage may include boron. An oxide layer 104 is formed on the substrate 100. The oxide layer may be formed by thermally oxidizing the surface portion of the substrate 100. The oxide layer 104 that is formed on the substrate 100 in the first region may function as a tunnel oxide layer. Further, the oxide layer 104 formed on the substrate 100 in the second region may function as a gate oxide layer of the transistor of the peripheral circuit. A gate layer 106 is formed on the oxide layer 104. For example, the gate layer 106 may formed by depositing a polysilicon carbide layer and a polysilicon layer. As another example embodiment, the gate layer 106 may be formed by depositing a polysilicon layer.

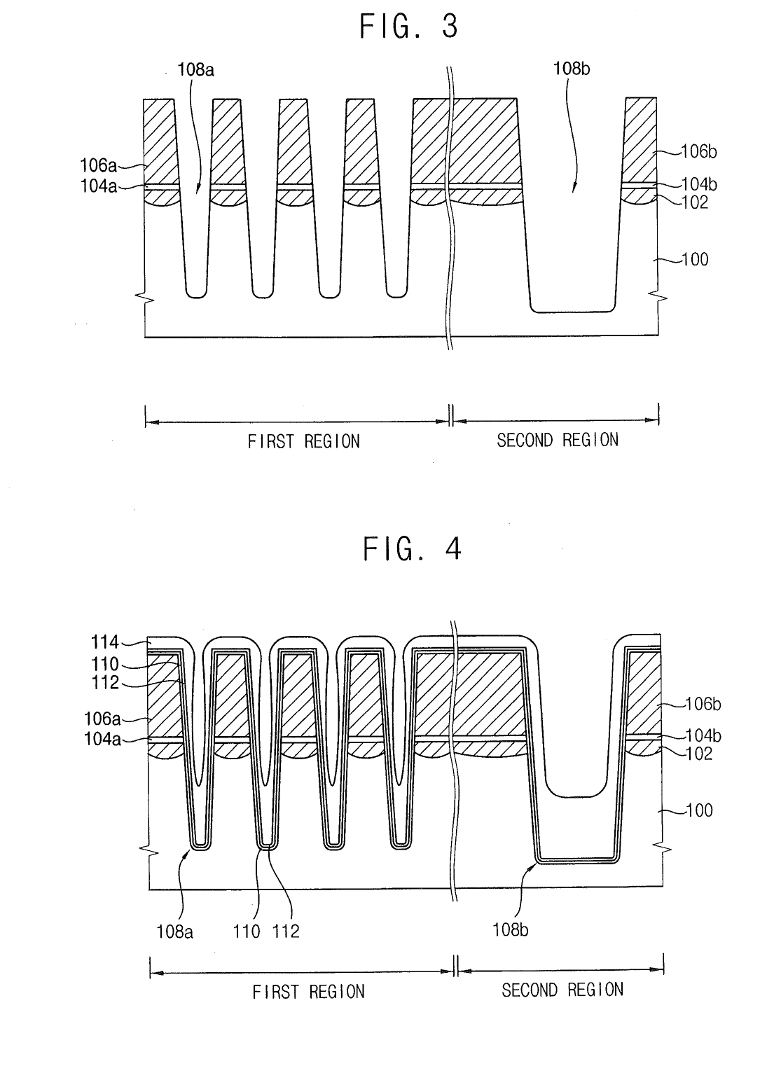

Referring to FIG. 3, the gate layer 106 and the oxide layer 104 in the field region are etched through a photolithography process. Thus, a tunnel oxide layer pattern 104a and floating gate electrodes 106a are formed on the substrate in the first region. Further, a gate oxide layer pattern 104b and gate electrodes 106b are formed on the substrate in the second region. The floating gate electrodes 106a formed on the substrate 100 in the first region may have a shape of line and space that are repeatedly formed. The line and space have a first width and a first gap. The first width may be no more than 30 nm. The gate electrodes 106b that are formed on the substrate 100 in the second region may have a second width that is wider than the first width and a second gap that is wider than the first gap. The substrate 100 is anisotropically etched using the floating gate electrodes 106a and the gate electrodes 106b as an etching mask. Through this etching process, the substrate 100 has a first trench 108a in the first region and a second trench 108b in the second region. That is, in accordance with this example embodiment, through the above one etching process, the first trench 108a having a relatively narrow width and the second trench 108b having a relatively wide width are simultaneously formed. The first trench 108a may have a narrow width that is no more than 30 nm.

When the above etching process is performed, the first and second trenches 108a and 108b may have different depth due to a loading effect. This loading effect means a phenomenon that an etching rate is reduced due to the insufficiency of the etchant or etching gas that is reacted with the substrate. The loading effect may be divided into a micro loading effect and a macro loading effect. The micro loading effect means a phenomenon that the etching rate is changed since the etching gas is not sufficiently supplied to a deep position between the patterns as the aspect ratio of the patterns increases. The macro loading effect means a phenomenon that the etching rate is changed according to the density of other etched patterns that are formed around the etched patterns. In the meantime, the floating gate electrodes 106a may have a density greater than that of the gate electrode 106b. Further, the first trench 108a has a higher aspect ratio than the second trench 108b. Thus, the etching loading effect in the first region becomes greater than in the second region and the substrate in the first region is etched slower than the substrate in the second region. Therefore, as shown in the figures, the first trench 108a comes to have a shallower depth than the second trench 108b.

Referring to FIG. 4, the surfaces of the sidewall of the first and second trench 108a and 108b is oxidized to form a sidewall oxide layer 110. A first liner layer 112 is formed on the sidewall oxide layer 110. The first liner layer 112 may comprise a silicon oxide type material. For example, the first liner layer 112 may be formed by using middle temperature oxide. The first liner layer 112 is formed so as to suppress the impurities 102 doped into the surface portion of the substrate 100 from diffusing into the first and second trenches 108a and 108b. When silicon nitride is used for the first liner layer 112, there would be an effect that the diffusion of the impurities is suppressed. However, the electrons may trapped by the first liner layer 112. Thus, when an isolation layer of a nonvolatile memory device is formed, using silicon nitride for the first liner layer 112 may be avoided. A first lower insulation layer 114 is formed on the first liner layer 112 so as to partially fill up the first and second trenches 108a, 108b. The first lower insulation layer 114 may be formed by using a material that hardly incur any dislocation when the first and second trenches 108a and 108b are filled up with the first lower insulation layer 114. Also, the first lower insulation layer 114 may comprise a material that suppresses the diffusion of the impurities 102 for controlling the threshold voltage. Examples of a material that may be used for the first lower insulation layer 114 may include undoped silicate glass (USG). In other example embodiments, examples of a material for the first lower insulation layer 114 may comprise high density plasma oxide (HDP oxide), middle temperature oxide (MTO), hot temperature oxide (HTO), ozone-TEOS, etc.

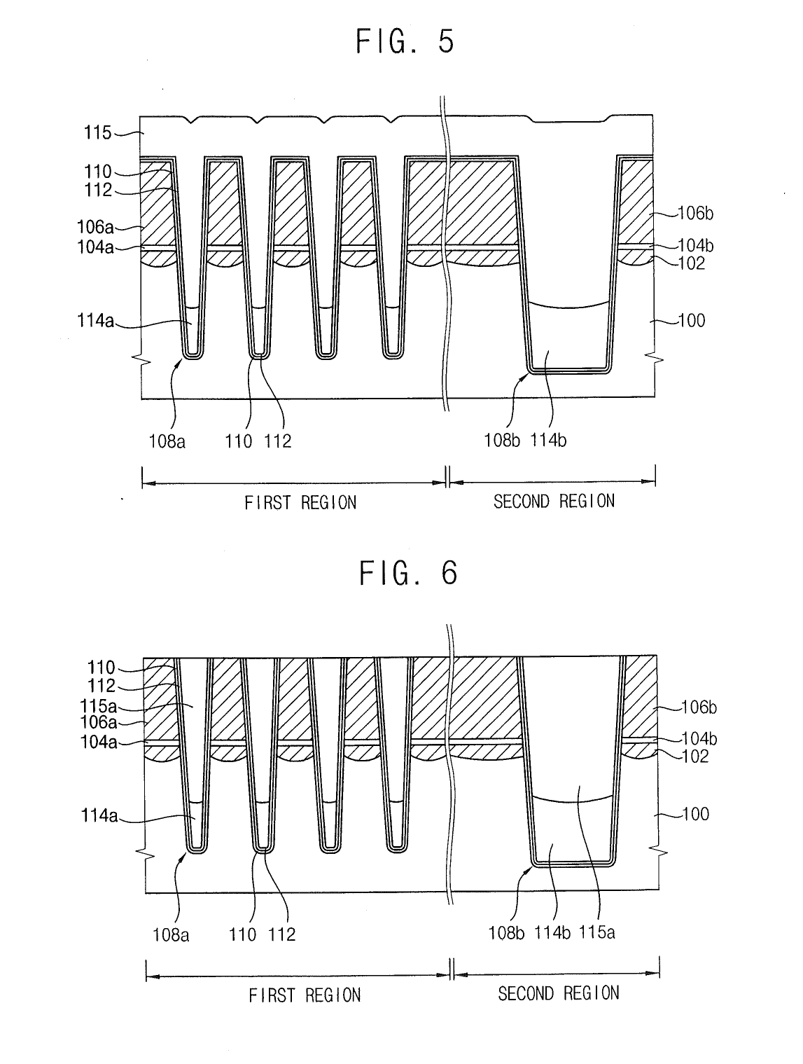

Referring to FIG. 5, the first lower insulation layer 114 is etched back so as to form first lower insulation layer patterns 114a, 114b. The first lower insulation layer patterns 114a, 114b are formed so as to reduce the aspect ratio of the first and second trenches 108a and 108b. Thereafter, a first upper insulation layer 115 is formed so as to fill up the first and second trenches 108a and 108b having the first lower insulation layer patterns 114a and 114b therein, respectively. The first upper insulation layer 115 may be formed by using a same material as the first lower insulation layer 114.

Referring to FIG. 6, the first upper insulation layer 115 is polished so as to expose the upper surfaces of the floating gate electrodes 106a, thereby forming a first preliminary upper pattern 115a. During the above polishing process, the portions of the first liner layer 112 and the sidewall oxide layer 110 that are formed on the upper surface of the floating gate electrode 106a are removed. In this example embodiment, the deposition of the first lower insulation layer 114, the etching back of the first lower insulation layer 114, the deposition of the first upper insulation layer 115 and the polishing of the first upper insulation layer 115 are sequentially performed to form the first preliminary insulation layer pattern 115a. By using these two deposition processes of the insulation layer, a void formation at the lower portion of the first preliminary insulation layer pattern 115a may be suppressed. However, when the aspect ratios of the first and second trenches 108a and 108b are not large, a deposition of an insulation layer and a polishing process of the insulation layer may be performed once to form the first preliminary insulation layer pattern 115a.

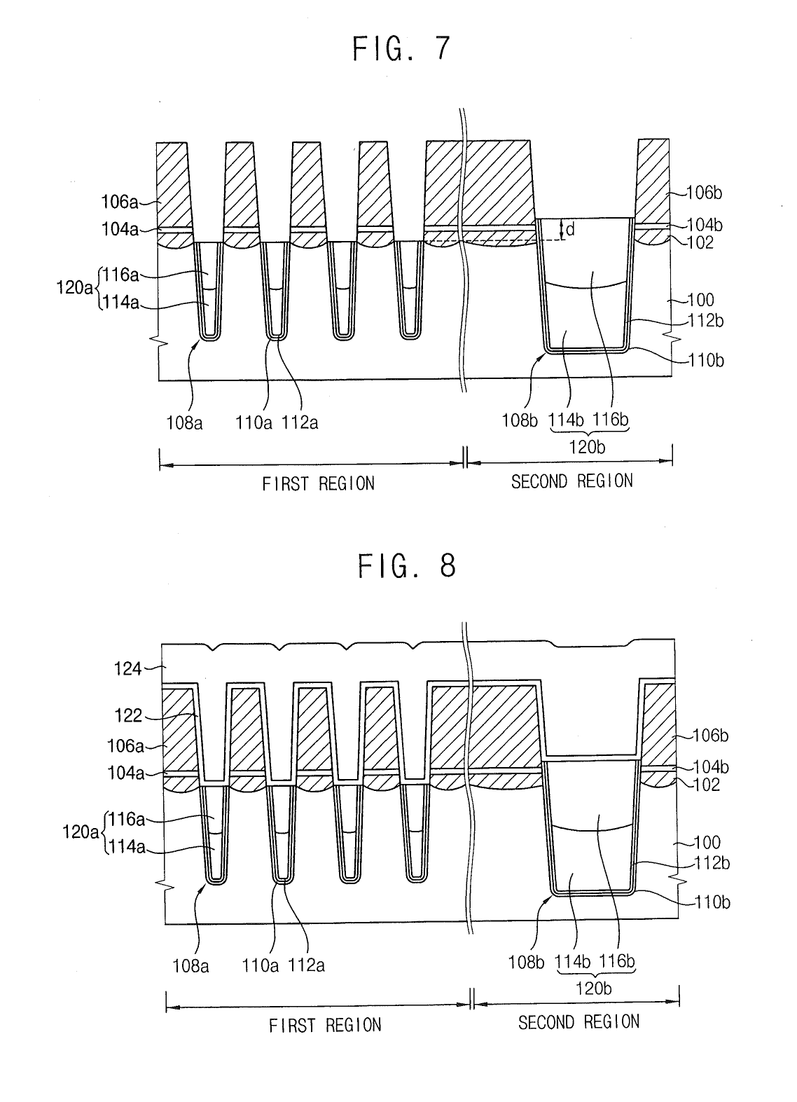

Referring to FIG. 7, the first preliminary insulation layer pattern 115a is etched back so as to form first and second upper insulation layer pattern 116a and 116b. Through the above process, a first insulation layer pattern 120a comprising the first lower insulation layer pattern 114a and the first upper insulation layer pattern 116a stacked thereon is formed in the first trench 108a. Further, a second insulation layer pattern 120b comprising the second lower insulation layer pattern 114b and the second upper insulation layer pattern 116b stacked thereon is formed in the second trench 108b. As shown in the figure, the second insulation layer pattern 120b has an upper surface that is higher than that of the first insulation layer pattern 120a (refer to d). That is, when the above etching back is performed, the first preliminary insulation layer pattern 115a in the first trench 108a is etched more slowly than the first preliminary insulation layer pattern 115a in the second trench 108b. Thus, only one etching back may form the first and second insulation layer pattern 120a and 120b having different heights. The width of the first trench 108a is much smaller than that of the second trench 108b. Thus, when the smaller amount of the etchant gas is introduced into the first trench 108a than the second trench 108b, the etching rate of the first preliminary insulation layer pattern 115a in the first trench 108a becomes relatively slow. In one example embodiment, the upper surface of the first insulation layer pattern 120a is lower than the upper surface of the tunnel oxide layer pattern 104a. That is, in this example embodiment, the first insulation layer pattern 120a is not formed at a gap between the adjacent floating gate electrodes 106a. In another example embodiment, the upper surface of the second insulation layer pattern 120b is higher than the upper surface of the gate oxide layer pattern 104b. Therefore, only the second insulation layer pattern 120b is provided on the sidewalls of the second trench 108b that has been formed by etching the substrate 100 in the second region. The second insulation layer pattern 120b comprises a material that suppresses the diffusion of the impurities. Thus, the second insulation layer pattern 120b may reduce the diffusion of the impurities into the second trench 108b, which have been doped into the substrate in the peripheral region for controlling the threshold voltage. During the etching process, the first liner layer 112 and the sidewall oxide layer 110 are partially etched to form the first liner layer patterns 112a and the first sidewall oxide layer pattern 110a in the first region and the second liner layer patterns 112b and the second sidewall oxide layer pattern 110b in the second region.

Referring to FIG. 8, a second liner layer 122 is formed along the profile of the inner sidewall of the first trench 108a, the first insulation layer pattern 120a, the floating gate electrode 106a, the inner sidewall of the second trench 108b, the second insulation layer pattern 120b and the gate electrode 106b. The second liner layer 122 may be formed by depositing a same material as the first liner layer 112. A second insulation layer 124 is formed on the second liner layer 122 to fill up the first and second trenches 108a and 108b. The second insulation layer 124 may be formed by using a material that does not form a void in the first trench 108 having a width no more than 30 nm. Particularly, the second insulation layer 124 may comprise TOSZ (Tonen silazene) that is an inorganic polysilazane-type SOG. However, when the second insulation layer 124 is formed by using a material such as USG (Undoped Silicate Glass), HDP (High Density Plasma) oxide, MTO (Middle Temperature Oxide), HTO (Hot Temperature Oxide), etc, there is a possibility that a void may be formed, which is undesirable. Particularly, the second insulation layer 124 may be formed as follows. TOSZ (Tonen silazene) that is an inorganic polysilazane-type SOG is coated to form a TOSZ layer on the second liner layer 122. The coated TOSZ layer is prebaked at a temperature of 150 to 250° C. and then hard baked at a temperature of 700 to 850° C. to form the second insulation layer 124. The second insulation layer 124 has a very small area that makes directly contact with the substrate 100. Thus, although the second insulation layer 124 may be formed by using TOSZ (Tonen silazene), a crack defect due to the dislocation hardly occur in the first and second trenches 108a and 108b of the substrate 100.

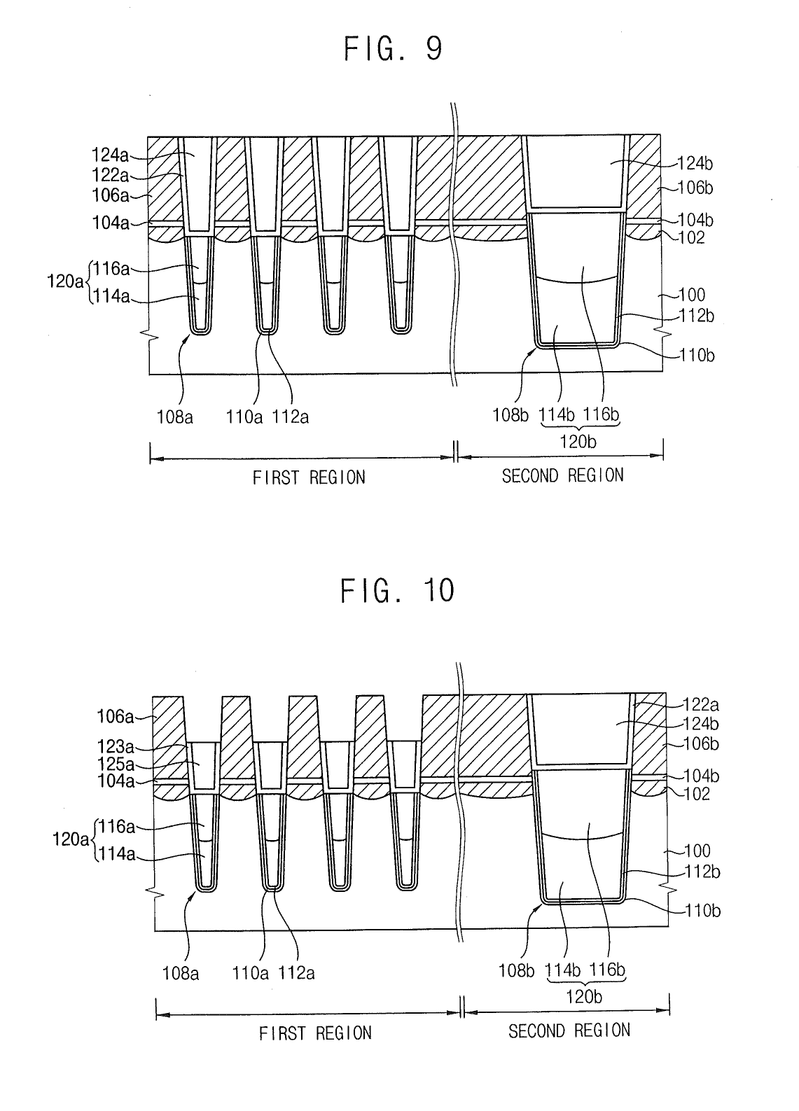

Referring to FIG. 9, the second insulation layer 124 is polished until the upper surfaces of the floating gate electrode 106a and the gate electrode 106b are exposed. Accordingly, a preliminary third insulation layer pattern 124a is formed in the first trench 108a and a fourth insulation layer pattern 124b is formed in the second trench 108b. Further, through the polishing process, the second liner layer 122 on the floating gate electrode 106a and the gate electrode 106b is partially removed to form a second liner layer pattern 122a.

Referring to FIG. 10, a photoresist film (not shown) is coated to cover the structure having the preliminary insulation layer pattern 124a and the fourth insulation layer pattern 124b. The photoresist film is exposed to light and then developed to form a photoresist pattern that covers the substrate 100 in the second region. Using the photoresist pattern as an etching mask, the upper portion of the preliminary third insulation layer pattern 124a is etched to form a third insulation layer pattern 125a. The third insulation layer pattern 125a thus formed by the above etching process may be higher than the upper surface of the tunnel oxide layer pattern 104a. When the above etching process is performed, the second liner layer pattern 122a is also partially etched to form a third liner layer pattern 123a. Accordingly, the upper sidewall portion and the upper surface of the floating gate electrode 106a are exposed where the preliminary third insulation layer pattern 124a is etched. When a void is formed in the preliminary third insulation layer pattern 124a, the void portion of the preliminary third insulation layer pattern 124a may be excessively etched during the above etching process, the third insulation layer pattern 125a may not normally formed. However, since the preliminary third insulation layer pattern 124a may comprise an inorganic polysilazane-type SOG that has a good gap-filling characteristic, there would be no void in the preliminary third insulation layer pattern 124a. So, the preliminary third insulation layer pattern 124a may be etched to a designated thickness and the preliminary third insulation layer pattern 124a that is higher than the bottom surface of the floating gate electrode 106a may be formed.

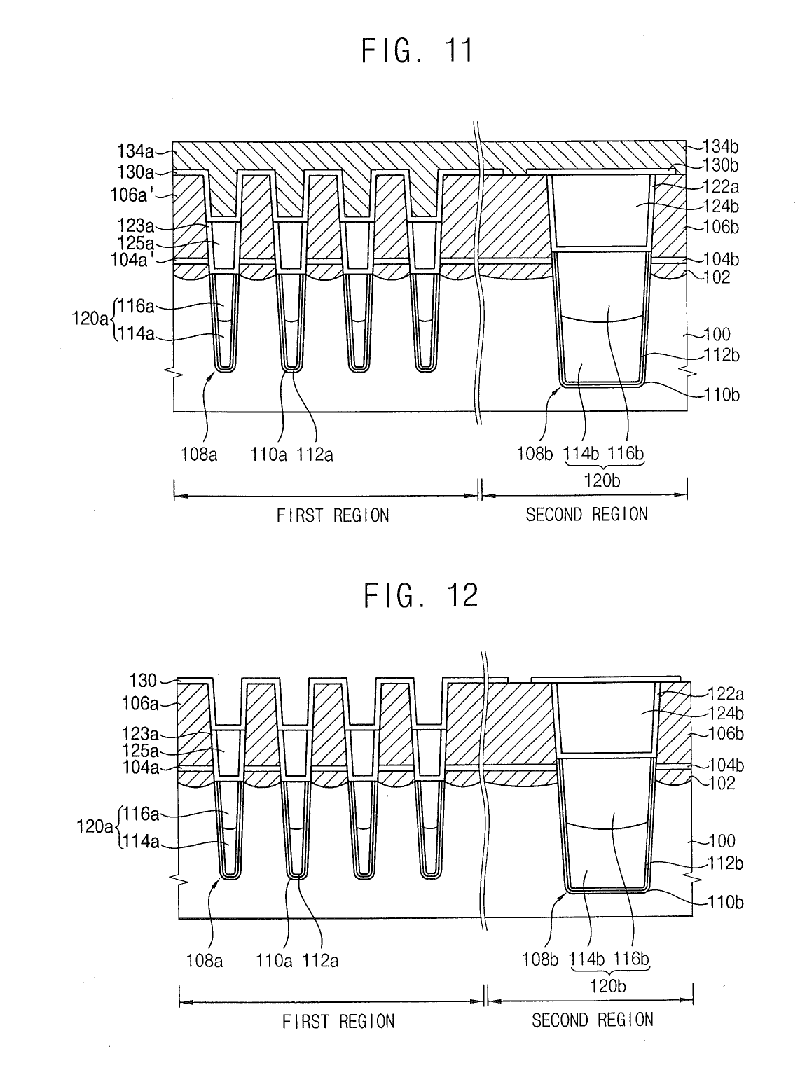

FIG, 11 is a cross-sectional view illustrating a nonvolatile memory device in accordance with example embodiments. Referring to FIG. 11, the nonvolatile memory device has cell transistors in the first region of the substrate 100 and peripheral transistors in the second region of the substrate 100. An isolation structure is formed at the substrate 100 for dividing the first and second regions. The isolation layer structure is the same as that in FIG. 1 except that a floating gate electrode 106a′ and a tunnel oxide layer pattern 104a′ have a shape of an isolated island. Regarding the isolation structure formed in the first region of the substrate, a blocking dielectric layer pattern 130a and a control gate electrode 134 are formed on the isolated floating gate electrode 106a′ and the third insulation layer pattern 125a. The blocking dielectric layer pattern 130a and the control gate electrode 134 have a line shape that is extended in the second direction that is perpendicular to the extended direction of the first trench. The blocking dielectric layer pattern 130a may have an ONO layer structure wherein oxide layer/nitride layer/oxide layer are sequentially stacked. In other example embodiment, the blocking dielectric layer pattern 130a may have a metal oxide having a high dielectric constant for increasing the capacitance of the blocking dielectric layer pattern 130a. Example of the metal oxide may include hafnium oxide, titanium oxide, tantalum oxide, zirconium oxide, aluminum oxide, etc. These may be used alone or in a combination thereof.

As for the material for the control gate electrode 134a, polysilicon, a metal, a metal nitride, a metal silicide, etc. may be mentioned. These can be used alone or in a combination thereof. In another example embodiment, the control gate electrode 130a may include a doped polysilicon layer, an ohmic layer, a diffusion barrier layer, a metal silicide layer and a metal layer that are sequentially stacked. Examples of a material that may be used for the ohmic layer may include titanium (Ti), tantalum (Ta), tungsten (W), molybdenum (Mo), or an alloy thereof. These may be used alone or in a combination thereof. Examples of a material that may be used for the diffusion barrier layer may include tungsten nitride, titanium nitride, tantalum nitride, molybdenum nitride, etc. These may be used alone or in a combination thereof. Examples of a material that may be used for the silicide layer may include tungsten silicide (WSix), titanium silicide (TiSix), molybdenum silicide (MoSix), tantalum silicide (TaSix), etc. These may be used alone or in a combination thereof. Examples of a material that may be used for the metal layer may include tungsten, titanium, tantalum, molybdenum, or an alloy thereof. In the isolation structure formed on the substrate in the second region, a remaining dielectric layer pattern 130b and an upper gate electrode 134b are provided on the surface of the gate electrode 106b and the fourth insulation layer pattern 134b.

The remaining dielectric layer pattern 130b may comprise a same material as the blocking dielectric layer pattern 130a. The remaining dielectric layer pattern 134b has an opening for exposing the upper surface of the gate electrode 106b. The upper gate electrode 134b may comprise a same material as the control gate electrode 134a. The upper gate electrode 134b may be electrically coupled to the upper surface of the gate electrode 106b.

FIG. 12 is a cross-sectional view illustrating a method of manufacturing a nonvolatile memory device as shown in FIG. 11. Firstly, the same procedures as shown in FIGS. 2 through 10 are performed to form the isolation structure as shown in FIG. 10. Referring to FIG. 12, a dielectric layer is continuously formed on the surfaces of the floating gate electrode 106a, the third insulation layer pattern 125a, the gate electrode 106b and the fourth insulation layer pattern 124b. In one example embodiment, the dielectric layer may be formed to have an ONO layer structure wherein oxide layer/nitride layer/oxide layer are sequentially stacked. In another example embodiment, the dielectric layer may be formed by using a metal oxide having a high dielectric constant. When the third insulation layer pattern 125a has a deep gap towards the substrate due to a void, the dielectric layer also may have a deep gap along the profile of the third insulation layer pattern 125 and the contact area between the floating gate electrode 106a and the dielectric layer may not be uniformly formed.

However, in the isolation structure in accordance with the this example embodiment, the void generation in the third insulation layer pattern 125a and the fourth insulation layer pattern 124b is suppressed and thus the defect due to the void may be prevented in the third insulation layer pattern 125a and the fourth insulation layer pattern 124b. Accordingly, the third insulation layer pattern 125a and the fourth insulation layer pattern 124b may be formed to have designated heights so that the contact area between the floating gate electrode 106a and the dielectric layer may be uniformly formed. Thus, cell transistors having uniform electrical characteristics may be formed in the first region of the substrate.

Thereafter, at least a portion the dielectric layer formed on the gate electrode 106b in the second region may be etched to form a preliminary dielectric layer pattern 130. Through this etching procedure, the preliminary dielectric layer pattern 130 may have an opening that exposes at least a portion of the surface of the gate electrode 106b.

Referring back to FIG. 11, a control gate electrode layer is formed on the preliminary dielectric layer pattern 130. As for the material for the control gate electrode layer, polysilicon, a metal, a metal nitride, a metal silicide, etc. may be mentioned. These can be used alone or in a combination thereof. In one example embodiment, the control gate electrode layer may include a doped polysilicon layer, an ohmic layer, a diffusion barrier layer, a metal silicide layer and a metal layer that are sequentially stacked. Thereafter, a photolithography process is performed to partially remove the control electrode layer, the preliminary dielectric layer pattern 130, floating gate electrode 106a, the tunnel oxide layer pattern 104a in the first region. Accordingly, the isolated tunnel oxide layer pattern 104a′ and the isolated floating gate electrode 106a′ are formed in the first region of the substrate 100. Further, on the isolated floating gate electrode 106a′, the blocking dielectric layer pattern 130a and the control gate electrode 134a are formed so as to extend in the second direction.

Another photolithography process is performed to pattern the control gate electrode layer, thereby forming the upper gate electrode 134b that is electrically coupled to the gate electrode 106b. Therefore, the oxide layer pattern 104b, the gate electrode 134b, the remaining dielectric layer pattern 130b and the upper gate electrode 134b are stacked in the second region. As explained above, in accordance the example embodiment, the isolation layer structure may be formed through a simple process without the void formation. The method for forming the isolation layer structure in accordance with the example embodiment may be used for forming an isolation structure of various semiconductor devices. Particularly, the method for forming the isolation layer structure in accordance with the example embodiment may be used for forming the isolation layer pattern of a nonvolatile memory device. The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of forming an integrated circuit device, comprising:
forming an electrically conductive layer on a substrate;
patterning the electrically conductive layer into first and second electrically conductive patterns by selectively etching the electrically conductive layer to define an opening therein that exposes the substrate;
filling the opening with an inorganic polysilazane-type spin-on-glass (SOG) material to define a first electrically insulating region extending between the first and second electrically conductive patterns; and
partially removing the electrically insulating region from within the opening to expose sidewalls of the first and second electrically conductive patterns.

2. The method of claim 1, wherein said patterning is followed by selectively etching the substrate exposed by the opening to define a trench within the substrate; wherein said filling is preceded by forming a silicon oxide insulation pattern within the trench; and wherein said filling comprises depositing an inorganic polysilazane-type spin-on-glass (SOG) layer on the silicon oxide insulation pattern.

3. The method of claim 2, wherein said filling comprises filling the opening with a tonen silazene (TOSZ) material.

4. The method of claim 1, wherein said filling comprises filling the opening with a tonen silazene (TOSZ) material.

5. The method of claim 4, further comprising prebaking the TOSZ material at a temperature in a range from 150° C. to 250° C.

6. The method of claim 5, wherein said prebaking is followed by baking the TOSZ material at a temperature in a range from 700° C. to 850° C.

7. A method of forming a nonvolatile memory device, comprising:
forming first and second floating gate electrodes of first and second nonvolatile memory cells, respectively, at side-by-side locations on a substrate;
selectively etching the substrate to define a trench therein extending between the first and second floating gate electrodes;
at least partially filling the trench with a first electrical insulation pattern;
conformally depositing an inorganic polysilazane-type spin-on-glass (SOG) layer on the first and second floating gate electrodes and on the first electrical insulation pattern;
partially removing the inorganic polysilazane-type spin-on-glass (SOG) layer from between the first and second floating gate electrodes; and
forming a control gate electrode on upper sidewalls of the first and second floating gate electrodes and on a remaining portion of the inorganic polysilazane-type spin-on-glass (SOG) layer extending between the first and second floating gate electrodes.

8. The method of claim 7, wherein said conformally depositing an inorganic polysilazane-type spin-on-glass (SOG) layer comprises conformally depositing a tonen silazene (TOSZ) layer on the first and second floating gate electrodes and on the first electrical insulation pattern.

9. The method of claim 8, further comprising prebaking the TOSZ layer at a temperature in a range from 150° C. to 250° C.

10. The method of claim 9, wherein said prebaking is followed by baking the TOSZ layer at a temperature in a range from 700° C. to 850° C.

11. A method of forming an isolation layer structure, comprising:
forming a first gate structure on a first upper surface in a first region of a substrate and forming a second gate structure on a second upper surface in a second region of the substrate;
etching the substrate between the first and second gate structures to form a first trench with a first width and a second trench with a second width wider than the first width;
forming first and second insulation patterns by using silicon oxide, the first insulation pattern partially filling up the first trench, the second insulation pattern partially filling up the second trench and having an upper surface higher than the first insulation pattern;
applying an inorganic polysilazane-type SOG material that is different from first and second insulation layer patterns to fill up the first and second trenches, thereby forming a third preliminary insulation layer pattern and a fourth insulation layer pattern; and
partially removing the third preliminary insulation layer pattern so as to expose an upper portion of sidewalls of the first gate structure, thereby forming a third insulation layer pattern.

12. The method of forming an isolation layer structure as claimed in claim 11, wherein the first and second trenches are formed by performing an etching process once.

13. The method of forming an isolation layer structure as claimed in claim 11, wherein the first and second insulation layer patterns comprise at least one selected from the group consisting of undoped silicate glass (USG), high density plasma (HDP) oxide, middle temperature oxide (MTO), hot temperature oxide (HTO), and ozone-TEOS.

14. The method of forming an isolation layer structure as claimed in claim 11, wherein the first and second gate structures comprise first and second gate electrodes, respectively, the first insulating layer pattern has an upper surface lower than a bottom surface of the first gate electrode, and the second insulating layer pattern has an upper surface higher than a bottom surface of the second gate electrode.

15. The method of forming an isolation layer structure as claimed in claim 11, wherein forming the first and second insulation patterns comprises:
forming a first lower insulation layer that partially fills up the first and second trenches;
etching the first lower insulation layer to a predetermined thickness to form first lower insulation layer patterns in the first and second trenches;
forming a first upper insulation layer on the first lower insulation layer patterns to fill up the first and second trenches; and
etching the first upper insulation layer to different thicknesses in the first and second trenches to form the first and second insulation layer patterns.

16. The method of forming an isolation layer structure as claimed in claim 11, further comprising: doping impurities through a planar surface of the substrate for controlling a threshold voltage of a transistor.

17. The method of forming an isolation layer structure as claimed in claim 11, further comprising:
forming a sidewall oxide layer pattern making contact with inner sidewall and bottom surface of the first and second trenches, the sidewall oxide layer pattern facing the first and second insulation layer patterns; and
forming a first liner layer pattern on a surface of the sidewall oxide layer pattern, the first liner layer pattern comprising an oxide.

18. The method of forming an isolation layer structure as claimed in claim 11, further comprising: forming second liner layer patterns on sidewalls of the third and fourth insulation layer patterns and below bottom surfaces of the third and fourth insulation layer patterns, the second liner layer patterns comprising an oxide.

19-25. (canceled)
